(19) United States
(12) Patent Application Publication
(10) Pub. No.: US 2026/0020388 A1
(43) Pub. Date: Jan. 15, 2026

(54) LIGHT-EMITTING DEVICE AND DISPLAY APPARATUS

(71) Applicant: HKC CORPORATION LIMITED, Shenzhen (CN)

(72) Inventors: Guangjia WANG, Shenzhen (CN); Haijiang YUAN, Shenzhen (CN)

(73) Assignee: HKC CORPORATION LIMITED, Shenzhen (CN)

(21) Appl. No.: 19/259,333

(22) Filed: Jul. 3, 2025

(30) Foreign Application Priority Data
Jul. 9, 2024 (CN) 202410910049.4

(51) Int. Cl. H10H 20/831; H10H 20/84

(52) U.S. Cl. CPC H10H 20/8314; H10H 20/84

(57) ABSTRACT

A light-emitting device and a display apparatus are provided. The light-emitting device includes a light-emitting diode (LED), a first conductive member, and a second conductive member. The LED includes an N-type semiconductor layer, a light-emitting layer, and a P-type semiconductor layer which are stacked sequentially in a first direction, the light-emitting layer has a first side surface and a second side surface opposite to each other in a second direction, and the second direction intersects with the first direction. The first conductive member is disposed opposite to at least a portion of the first side surface. The second conductive member is disposed opposite to at least a portion of the second side surface, and the first conductive member is disposed opposite to at least a portion of the second conductive member.

### CROSS-REFERENCE TO RELATED APPLICATION(S)

This application claims priority to Chinese Patent Application No. 202410910049.4, filed Jul. 9, 2024, the disclosure of which is hereby incorporated by reference in its entirety.

### TECHNICAL FIELD

This application relates to the technical field of light-emitting devices, and particularly to a light-emitting device and a display apparatus.

### BACKGROUND

Light-emitting devices, such as Micro-Light-Emitting Diodes (Micro-LED), can emit lights through recombination of electrons and holes, and have advantages of high brightness, high contrast, wide color gamut, high resolution, fast response time, energy saving, and low power consumption, and thus are considered to be a new direction for development of display technologies.

In an existing semiconductor light-emitting device, electrons and holes have only a single main migration path, so that a probability of recombination between the electrons and the holes is relatively small, resulting in unsatisfactory luminous efficacy.

### SUMMARY

In a first aspect, the disclosure provides a light-emitting device. The light-emitting device includes a Light-Emitting Diode (LED), a first conductive member, and a second conductive member. The LED includes an N-type semiconductor layer, a light-emitting layer, and a P-type semiconductor layer which are stacked sequentially in a first direction, the light-emitting layer has a first side surface and a second side surface opposite to each other in a second direction, and the second direction intersects with the first direction. The first conductive member is disposed opposite to at least a portion of the first side surface. The second conductive member is disposed opposite to at least a portion of the second side surface, and the first conductive member is disposed opposite to at least a portion of the second conductive member.

In a second aspect, the disclosure provides a display apparatus. The display apparatus includes a drive backplane and light-emitting devices described in any one of the various embodiments of the first aspect and arranged in an array on the drive backplane.

### BRIEF DESCRIPTION OF THE DRAWINGS

In order to describe technical solutions of embodiments of the disclosure or the related art more clearly, the following will give a brief description of accompanying drawings used for describing the embodiments or the related art. Apparently, accompanying drawings described below are merely some embodiments. Those of ordinary skill in the art can also obtain other accompanying drawings based on the accompanying drawings described below without creative efforts.

FIG. 1 is a schematic diagram illustrating a light-emitting device provided in embodiments.

FIG. 2 is a schematic diagram illustrating a light-emitting device provided in other embodiments.

FIG. 3 is a schematic diagram illustrating a light-emitting device provided in other embodiments.

FIG. 4 is a schematic diagram illustrating a light-emitting device provided in other embodiments.

FIG. 5 is a schematic diagram illustrating distribution of electrons and holes in a light-emitting layer provided in embodiments.

FIG. 6 is a schematic diagram illustrating a display apparatus provided in embodiments.

Description of reference signs: 1000—display apparatus; 100—light-emitting device; 10—first conductive member; 20—second conductive member; 31—light-emitting layer, 311—first side surface, 312—second side surface, 313—third side surface, 314—fourth side surface, 32—N-type semiconductor layer, 33—P-type semiconductor layer, 34—first current diffusion layer, 35—second current diffusion layer, 36—substrate, 37—N electrode, 38—P electrode; 40—first insulating portion; 50—second insulating portion, 51—first sub-portion, 52—second sub-portion; 60—third conductive member; 70—fourth conductive member; 80—third insulating portion; 90—fourth insulating portion; 200—drive backplane; Z—first direction, X—second direction, Y—third direction.

### DETAILED DESCRIPTION

Hereinafter, technical solutions of embodiments of the disclosure will be described clearly and completely with reference to accompanying drawings in the embodiments. Apparently, embodiments described below are merely some embodiments, rather than all embodiments of the disclosure. All other embodiments obtained by those of ordinary skill in the art based on the embodiments without creative efforts shall fall within the protection scope of the disclosure.

It is to be noted that, when a component is described as being “fixed to” another component, said component may be directly on said another component or may be on said another component via an intermediate component. Also, when a component is described as being “connected to/with” another component, said component may be directly connected to/with said another component or may be connected to/with said another component via an intermediate component.

Unless otherwise defined, all technical and scientific terms used in the disclosure have the same meaning as commonly understood by one of ordinary skill in the technical field to which the disclosure belongs. The terms used in the specification of the disclosure are merely for the purpose of describing embodiments of the disclosure, which are not intended to limit the disclosure. The term “and/or” used in the disclosure includes any and all combinations of one or more associated listed items.

The following provides a detailed description of some embodiments of the disclosure with reference to the accompanying drawings. The embodiments described below and features therein may be combined without conflict.

The disclosure provides a light-emitting device and a display apparatus, which can increase a probability of recombination between electrons and holes, thereby improving luminous efficacy.

In order to achieve the technical problem of the disclosure, the disclosure provides the following technical solutions.

In a first aspect, the disclosure provides a light-emitting device. The light-emitting device includes a Light-Emitting Diode (LED), a first conductive member, and a second conductive member. The LED includes an N-type semiconductor layer, a light-emitting layer, and a P-type semiconductor layer which are stacked sequentially in a first direction, the light-emitting layer has a first side surface and a second side surface opposite to each other in a second direction, and the second direction intersects with the first direction. The first conductive member is disposed opposite to at least a portion of the first side surface. The second conductive member is disposed opposite to at least a portion of the second side surface, and the first conductive member is disposed opposite to at least a portion of the second conductive member.

In an embodiment, the LED further includes a first current diffusion layer and a second current diffusion layer, the first current diffusion layer is stacked on the N-type semiconductor layer, the second current diffusion layer is stacked on the P-type semiconductor layer, and the first conductive member is disposed opposite to the second conductive member.

In an embodiment, the first side surface faces the first current diffusion layer, and the first conductive member is connected with the first current diffusion layer.

In an embodiment, the first conductive member is integrated with the first current diffusion layer.

In an embodiment, the second conductive member is connected with the second current diffusion layer, and the second conductive member extends along the first direction and is opposite to a side surface of the P-type semiconductor layer.

In an embodiment, the second conductive member is integrated with the second current diffusion layer.

In an embodiment, the light-emitting device satisfies at least one of the following arrangements: the first conductive member is spaced apart from the first current diffusion layer, or the second conductive member is spaced apart from the second current diffusion layer.

In an embodiment, the light-emitting device further includes a first insulating portion and a second insulating portion, the first insulating portion is disposed between the first side surface and the first conductive member, and the second insulating portion is disposed between the second side surface and the second conductive member.

In an embodiment, the light-emitting device further includes a third conductive member and a fourth conductive member, the light-emitting layer further has a third side surface and a fourth side surface opposite to each other in a third direction, the third direction intersects with the first direction and the second direction, the third conductive member is opposite to at least a portion of the third side surface, the fourth conductive member is opposite to at least a portion of the fourth side surface, and the third conductive member is opposite to at least a portion of the fourth conductive member.

In an embodiment, the first conductive member and the second conductive member each are made of an electrode material, or the first conductive member and the second conductive member each are made of a semiconductor material.

In a second aspect, the disclosure provides a display apparatus. The display apparatus includes a drive backplane and light-emitting devices described in any one of the various embodiments of the first aspect and arranged in an array on the drive backplane.

By providing such a light-emitting device, where the light-emitting device includes the N-type semiconductor layer, the light-emitting layer, and the P-type semiconductor layer which are stacked sequentially in the first direction, the first conductive member is opposite to at least a portion of the first side surface of the light-emitting layer, the second conductive member is disposed opposite to at least a portion of the second side surface of the light-emitting layer, and the first conductive member is disposed opposite to at least a portion of the second conductive member, a potential difference between the first conductive member and the second conductive member is generated when power on, to drive migration of electrons and holes, which can increase the main migration directions of the electrons and the holes and increase a probability of recombination between the electrons and the holes, thereby improving luminous efficacy of the light-emitting device.

Referring to FIG. 6, embodiments of the disclosure provide a display apparatus 1000. The display apparatus 1000 includes a light-emitting device(s) 100 of embodiments of the disclosure.

Optionally, the display apparatus 1000 may be a display screen, a television, an electronic device such as a mobile phone, a computer, etc., which is not limited herein.

Optionally, the display apparatus 1000 includes a drive backplane 200, and light-emitting devices 100 of embodiments of the disclosure are arranged in an array on the drive backplane 200.

Optionally, the light-emitting devices 100 are arranged in multiple rows and multiple columns on the drive backplane 200. The drive backplane 200 includes a drive circuit (not illustrated in the figures), the drive circuit is electrically connected with the light-emitting device 100, and the drive backplane 200 is configured to supply power to the light-emitting device 100 through the drive circuit.

The display apparatus 1000 of embodiments of the disclosure can have high luminous efficacy by using the light-emitting device 100 of embodiments of the disclosure.

The light-emitting device 100 of embodiments of the disclosure will be described in detail below.

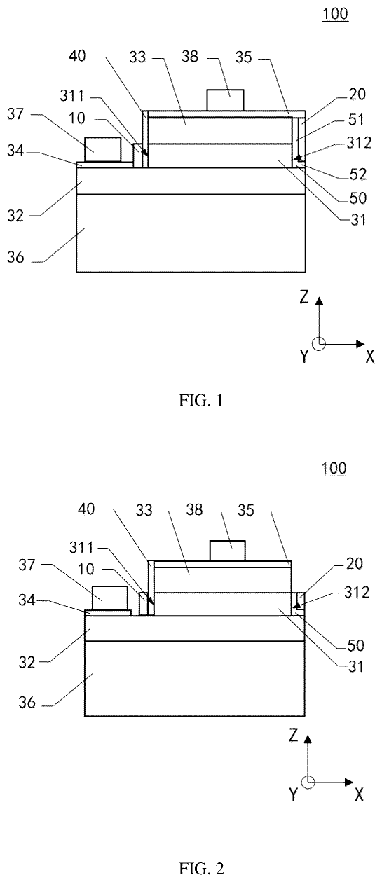

First, directions are defined. As illustrated in FIG. 1, Z is a first direction, X is a second direction, and Y is a third direction. The first direction Z, the second direction X, and the third direction Y intersect with one another.

Optionally, the first direction Z, the second direction X, and the third direction Y are perpendicular to one another.

Referring to FIG. 1, embodiments of the disclosure provide a light-emitting device 100. The light-emitting device 100 includes an LED, a first conductive member 10, and a second conductive member 20. The LED includes an N-type semiconductor layer 32, a light-emitting layer 31, and a P-type semiconductor layer 33 which are stacked sequentially in the first direction Z. The light-emitting layer 31 has a first side surface 311 and a second side surface 312 opposite to each other in the second direction X. The first conductive member 10 is disposed opposite to at least a portion of the first side surface 311, the second conductive member 20 is disposed opposite to at least a portion of the second side surface 312, and the first conductive member 10 is disposed opposite to at least a portion of the second conductive member 20. Optionally, the LED is an LED commonly used in the art, such as a Micro-LED, a Mini-LED, or the like, which is not limited herein.

Optionally, the first conductive member 10 and the second conductive member 20 each are made of an electrode material commonly used in the art, such as aluminum, silver, etc. In this case, the first conductive member 10 and the second conductive member 20 are used as electrodes. Alternatively, the first conductive member 10 and the second conductive member 20 each are made of a semiconductor material commonly used in the art, such as silicon, germanium, gallium nitride, aluminum nitride, silicon carbide, gallium arsenide, etc. In this case, the first conductive member 10 and the second conductive member 20 are used as current diffusion layers. The disclosure is not limited thereto.

Optionally, in an embodiment, as illustrated in FIG. 1, the first side surface 311 and the second side surface 312 are two opposite side surfaces of the light-emitting layer 31 in the second direction X, the first conductive member 10 is opposite to at least a portion of the first side surface 311 in the second direction X, and the second conductive member 20 is opposite to at least a portion of the second side surface 312 in the second direction X.

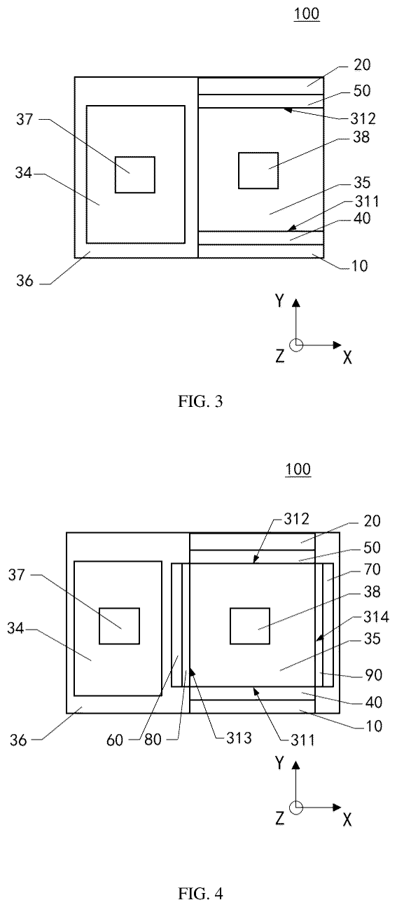

In another embodiment, as illustrated in FIG. 3, the first side surface 311 and the second side surface 312 are two opposite side surfaces of the light-emitting layer 31 in the third direction Y, the first conductive member 10 is opposite to at least a portion of the first side surface 311 in the third direction Y, and the second conductive member 20 is opposite to at least a portion of the second side surface 312 in the third direction Y.

Optionally, the first conductive member 10 is in connection with the first side surface 311, and this connection may be a direct connection or an indirect connection. Alternatively, the first conductive member 10 is spaced apart from the first side surface 311. The above arrangements are all possible, and no specific limitation is imposed herein. A connection manner between the second conductive member 20 and the second side surface 312 is similar to that between the first conductive member 10 and the first side surface 311, and reference can be made to the relevant description, which will not be repeated herein.

Semiconductor LEDs have advantages of high brightness, high contrast, wide color gamut, high resolution, fast response time, energy saving, and low power consumption, and thus are considered to be a new direction for development of display technologies.

For an existing light-emitting device 100, electrons in the light-emitting layer 31 are mainly distributed on one side of the light-emitting layer 31 connected with the N-type semiconductor layer 32 in the first direction Z, while holes in the light-emitting layer 31 are mainly gathered on one side of the light-emitting layer 31 connected with the P-type semiconductor layer 33 in the first direction Z. The main migration path of the electrons and the holes is only along a direction of a line connecting the electron-gathering side and the hole-gathering side of the light-emitting layer 31, that is, the first direction Z, so the migration path is relatively single, resulting in a relatively low probability of recombination between the electrons and the holes and relatively low luminous efficacy.

Optionally, in the existing light-emitting layer 31, the main migration path of the electrons and the holes is only along the direction of the line connecting the electron-gathering side and the hole-gathering side of the light-emitting layer 31, that is, the main migration direction of the electrons and the holes in the light-emitting layer 31 is only the first direction Z. In this case, the light-emitting layer 31 has a maximum contact surface for collision between the electrons and the holes, and the maximum contact surface is perpendicular to the direction of the line connecting the electron-gathering side and the hole-gathering side of the light-emitting layer 31, that is, the first direction Z.

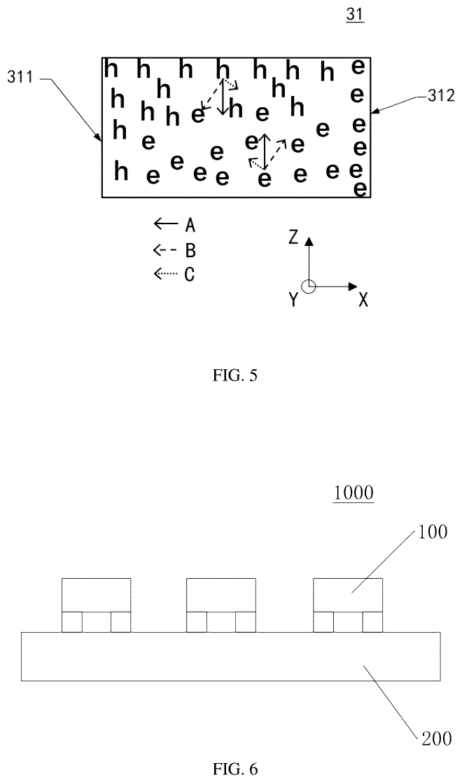

FIG. 5 illustrates a schematic diagram of distribution of electrons and holes in a cross section of the light-emitting layer 31 parallel to the first direction Z after power on, where e represents an electron, and h represents a hole. A is a main migration direction of the electrons and the holes in the light-emitting layer 31 driven by the N-type semiconductor layer 32 and the P-type semiconductor layer 33, B is a main migration direction of the electrons and the holes in the light-emitting layer 31 driven by the first conductive member 10 and the second conductive member 20, and C is a secondary migration direction. By providing the first conductive member 10 and the second conductive member 20, after power on, the electrons and the holes can move in direction B under action of the first conductive member 10 and the second conductive member 20 in addition to moving in direction A under action of a voltage of the LED, thereby increasing the main migration directions of the electrons and the holes.

In this case, the maximum contact surface of the electrons and the holes is parallel to a diagonal line of the cross section of the light-emitting layer 31 parallel to the first direction Z, and the electrons and the holes are respectively gathered on two sides of the diagonal line. As such, the main migration directions of the electrons and the holes and the area of the maximum contact surface can be increased, that is, a probability of recombination between the electrons and the holes can be increased, thereby improving luminous efficacy of the light-emitting device 100.

According to the light-emitting device 100 of embodiments of the disclosure, the light-emitting device 100 includes the N-type semiconductor layer 32, the light-emitting layer 31, and the P-type semiconductor layer 33 which are stacked sequentially in the first direction Z, the first conductive member 10 is disposed opposite to at least a portion of the first side surface 311 of the light-emitting layer 31, the second conductive member 20 is disposed opposite to at least a portion of the second side surface 312 of the light-emitting layer 31, and the first conductive member 10 is disposed opposite to at least a portion of the second conductive member 20. With such light-emitting device 100, a potential difference between the first conductive member 10 and the second conductive member 20 is generated when power is applied, to drive migration of electrons and holes, which can increase the main migration directions of the electrons and the holes and increase a probability of recombination between the electrons and the holes, thereby improving luminous efficacy of the light-emitting device 100.

In addition, there is a high probability that electrons and holes are gathered on side surfaces of the light-emitting layer 31 of the existing light-emitting device 100. Since there are relatively more defects on sidewalls of the light-emitting layer 31 (such as the first side surface 311 and the second side surface 312), electrons and holes gathered here leads to low luminous efficacy due to influence of these defects, thereby affecting the luminous efficacy of the light-emitting device 100. The light-emitting device 100 of the embodiments of the disclosure is provided with the first conductive member 10 and the second conductive member 20, since there is a potential difference between the first conductive member 10 and the second conductive member 20, either electrons or holes are distributed on a single sidewall of the light-emitting layer 31, which can reduce recombination on the sidewall and avoid a reduction in the number of electrons and holes caused by abnormal recombination of electrons and holes, thereby improving luminous efficacy of the light-emitting device 100.

Optionally, as illustrated in FIG. 1, the LED further includes a first current diffusion layer 34 and a second current diffusion layer 35. The first current diffusion layer 34 is stacked on the N-type semiconductor layer 32, the second current diffusion layer 35 is stacked on the P-type semiconductor layer 33, and the first conductive member 10 is disposed opposite to the second conductive member 20.

Optionally, the LED further includes a substrate 36. The N-type semiconductor layer 32 is stacked on the substrate 36, or the P-type semiconductor layer 33 is stacked on the substrate 36, which is not limited herein.

Optionally, in an embodiment, the material of the N-type semiconductor layer 32 is N-type Gallium Nitride (N-GaN), which is formed by doping N-type impurities (e.g., silicon, sulfur, etc.) in the gallium nitride material; the material of the P-type semiconductor layer 33 is P-type Gallium Nitride (P-GaN), which is formed by doping P-type impurities (e.g., magnesium, zinc, etc.) in the gallium nitride material, and there is no specific limitation.

Optionally, as illustrated in FIG. 1, the LED further includes an N electrode 37 and a P electrode 38, the N electrode 37 is electrically connected with the first current diffusion layer 34, and the P electrode 38 is electrically connected with the second current diffusion layer 35. The first current diffusion layer 34 is disposed between the N electrode 37 and the N-type semiconductor layer 32, and the second current diffusion layer 35 is disposed between the P electrode 38 and the P-type semiconductor layer 33, which can effectively reduce a contact resistance, thereby improving a conductive performance.

Optionally, the light-emitting layer 31 has a Multi-Quantum Well (MQW) structure. In an embodiment, the light-emitting layer 31 is formed by alternating growth of Indium Gallium Nitride (InGaN) and Gallium Nitride (GaN).

Optionally, the first conductive member 10 and the second conductive member 20 may be completely opposite to each other, or may be partially opposite to each other, so that at least a portion of the light-emitting layer 31 is located within an electric field formed between the first conductive member 10 and the second conductive member 20.

In the light-emitting device 100 of embodiments of the disclosure, in addition to moving mainly in a stacking direction of the N-type semiconductor layer 32 and the P-type semiconductor layer 33 (i.e., the first direction Z), the electrons and the holes in the light-emitting layer 31 can move, driven by the first conductive member 10 and the second conductive member 20, between one side of the light-emitting layer 31 where the first conductive member 10 is disposed and another side of the light-emitting layer 31 where the second conductive member 20 is disposed, which can increase the main migration paths of the electrons and the holes, and improve a probability of recombination between the electrons and the holes, thereby improving luminous efficacy of the light-emitting device 100.

Optionally, the first conductive member 10 is connected with the first current diffusion layer 34, and/or the second conductive member 20 is connected with the second current diffusion layer 35.

Optionally, the first conductive member 10 is connected with the first current diffusion layer 34, and the second conductive member 20 is connected with the second current diffusion layer 35. Alternatively, the first conductive member 10 is connected with the first current diffusion layer 34, and the second conductive member 20 is spaced apart from the second current diffusion layer 35. Alternatively, the first conductive member 10 is spaced apart from the first current diffusion layer 34, and the second conductive member 20 is connected with the second current diffusion layer 35. The above arrangements are all possible, and no specific limitation is imposed herein.

By providing the first conductive member 10 to be connected with the first current diffusion layer 34, and/or providing the second conductive member 20 to be connected with the second current diffusion layer 35, the first conductive member 10 can be energized through the N electrode 37 connected with the first current diffusion layer 34 when the first conductive member 10 is connected with the first current diffusion layer 34, and the second conductive member 20 can be energized through the P electrode 38 connected with the second current diffusion layer 35 when the second conductive member 20 is connected with the second current diffusion layer 35.

Optionally, as illustrated in FIG. 1, the first side surface 311 faces the first current diffusion layer 34, and the first conductive member 10 is connected with the first current diffusion layer 34.

Optionally, in an embodiment, the first conductive member 10 is an N-type current diffusion layer, the first conductive member 10 is disposed on one side of the first side surface 311 in the second direction X, the first conductive member 10 is connected with the first current diffusion layer 34, and the first conductive member 10 is located between the first current diffusion layer 34 and the first side surface 311.

Due to the small size of the light-emitting device 100, when the first conductive member 10 is an N-type current diffusion layer and connected with the first current diffusion layer 34, if the first conductive member 10 and the first current diffusion layer 34 are respectively located on one side of two adjacent side surfaces of the light-emitting layer 31, the processing difficulty would be relatively high. Therefore, the first conductive member 10 is located between the first current diffusion layer 34 and the first side surface 311 to facilitate fabrication.

Optionally, the first conductive member 10 is integrated with the first current diffusion layer 34.

Optionally, the first conductive member 10 and the first current diffusion layer 34 may be in an integrated structure formed through a one-piece process, or the first conductive member 10 and the first current diffusion layer 34 may be in a separate structure, and may be connected to each other by bonding, clamping, etc., which is not limited herein.

By providing the first conductive member 10 and the first current diffusion layer 34 to be in an integrated structure, the first conductive member 10 and the first current diffusion layer 34 can be formed on the N-type semiconductor layer 32 through one same operation, which can save operations of the manufacturing process.

Optionally, as illustrated in FIG. 1, the second conductive member 20 is connected with the second current diffusion layer 35, and the second conductive member 20 extends along the first direction Z and is opposite to a side surface of the P-type semiconductor layer 33.

Optionally, the second current diffusion layer 35 is disposed on a surface of the P-type semiconductor layer 33 facing away the light-emitting layer 31 in the first direction Z.

Optionally, in an embodiment, the second conductive member 20 is a P-type current diffusion layer, the second conductive member 20 is disposed on one side of the second side surface 312 in the second direction X, and the second conductive member 20 extends along the first direction Z from the second current diffusion layer 35 to the second side surface 312 of the light-emitting layer 31, and is opposite to a side surface of the P-type semiconductor layer 33.

Optionally, the first conductive member 10 may also shield, in the first direction Z, at least a portion of a side surface of the P-type semiconductor layer 33, provided that the first conductive member 10 is spaced apart from the second current diffusion layer 35.

Since the second conductive member 20 is a P-type current diffusion layer, the second conductive member 20 needs to be connected with the second current diffusion layer 35 to be electrically connected with the P electrode 38, in order for an electric field to be generated between the second conductive member 20 and the first conductive member 10 when power on. The light-emitting layer 31 needs to be located in the electric field generated between the second conductive member 20 and the first conductive member 10, and the second current diffusion layer 35 is disposed on a surface of the P-type semiconductor layer 33 facing away the light-emitting layer 31. Therefore, the second conductive member 20 extends along the first direction Z, and is opposite to a side surface of the P-type semiconductor layer 33 and at least a portion of the second side surface 312, so that at least a portion of the light-emitting layer 31 is located within the electric field formed between the first conductive member 10 and the second conductive member 20.

Optionally, the second conductive member 20 is integrated with the second current diffusion layer 35.

Optionally, the second conductive member 20 and the second current diffusion layer 35 may be in an integrated structure formed through a one-piece process, or the second conductive member 20 and the second current diffusion layer 35 may be in a separate structure, and may be connected to each other by bonding, clamping, etc., which is not limited herein.

By providing the second conductive member 20 and the second current diffusion layer 35 to be in an integrated structure, the second conductive member 20 and the second current diffusion layer 35 can be formed through one same operation, which can save operations of the manufacturing process.

Optionally, the first conductive member 10 is spaced apart from the first current diffusion layer 34, and/or the second conductive member 20 is spaced apart from the second current diffusion layer 35.

Optionally, the first conductive member 10 is an electrode, and the first current diffusion layer 34 is disposed on one side of the first side surface 311 in the second direction X. The first conductive member 10 is disposed between the first side surface 311 and the first current diffusion layer 34 in the second direction X, and the first conductive member 10 is spaced apart from the first current diffusion layer 34; alternatively, the first conductive member 10 is disposed on one side of the second side surface 312 in the second direction X; alternatively, the first conductive member 10 is disposed on one side of a side surface of the light-emitting layer 31 in the third direction Y. The above arrangements are all possible, and no specific limitation is imposed herein.

Alternatively, the first conductive member 10 is an N-type current diffusion layer, the first conductive member 10 is spaced apart from the first current diffusion layer 34, and the first conductive member 10 is externally connected with an electrode to control generation of a potential difference between the first conductive member 10 and the second conductive member 20.

Optionally, the second conductive member 20 is an electrode, the second conductive member 20 is spaced apart from the second current diffusion layer 35, and the second conductive member 20 is disposed on one side of a side surface of the light-emitting layer 31 facing away the first conductive member 10. The arrangement of the second conductive member 20 is similar to that of the first conductive member 10, reference can be made to the relevant description of the first conductive member 10, which will not be repeated herein.

Alternatively, the second conductive member 20 is a P-type current diffusion layer, the second conductive member 20 is spaced apart from the second current diffusion layer 35, and the second conductive member 20 is externally connected with an electrode to control generation of the potential difference between the first conductive member 10 and the second conductive member 20.

In an embodiment, as illustrated in FIG. 2, the first conductive member 10 is opposite to the first side surface 311 of the light-emitting layer 31 in the second direction X, and the first conductive member 10 is spaced apart from the first current diffusion layer 34; the second conductive member 20 is opposite to the second side surface 312 of the light-emitting layer 31 in the second direction X, and the second conductive member 20 is spaced apart from the second current diffusion layer 35.

Since the first conductive member 10 is spaced apart from the first current diffusion layer 34 and/or the second conductive member 20 is spaced apart from the second current diffusion layer 35, the first conductive member 10 and/or the second conductive member 20 can be independently controlled to be powered on and off, which allows independent control of an electric field strength between the first conductive member 10 and the second conductive member 20, thereby enabling optimization of luminous efficacy according to actual requirements.

Optionally, the light-emitting device 100 further includes a first insulating portion 40 and a second insulating portion 50, the first insulating portion 40 is disposed between the first side surface 311 and the first conductive member 10, and the second insulating portion 50 is disposed between the second side surface 312 and the second conductive member 20.

Optionally, the material of the first insulating portion 40 and the second insulating portion 50 may be an insulating material commonly used in the art, an inorganic insulating material such as Silicon Oxide (e.g., SiO₂), Silicon Nitride (e.g., Si₃N₄), Al₂O₃, TiO₂, etc., or an organic insulating material such as polyimide, polyparaxylene, polyphenylene sulfide, etc., which is not limited herein.

Optionally, the first insulating portion 40 and the second insulating portion 50 may be formed by Chemical Vapor Deposition (CVD), Physical Vapor Deposition (PVD), etc., which is not limited herein.

Optionally, in an embodiment, as illustrated in FIG. 1, the first conductive member 10 is disposed on one side of the first side surface 311 of the light-emitting layer 31 in the second direction X, a surface of the first insulating portion 40 in the second direction X is in connection with the first side surface 311, and the other surface of the first insulating portion 40 in the second direction X is in connection with the first conductive member 10, and the connection method is not limited herein. In another embodiment, as illustrated in FIG. 3, the first conductive member 10 is disposed on one side of the first side surface 311 of the light-emitting layer 31 in the third direction Y, a surface of the first insulating portion 40 in the third direction Y is connected with the first side surface 311, and the other surface of the first insulating portion 40 in the third direction Y is connected with the first conductive member 10. The above arrangement methods are all possible, and no specific limitation is imposed herein.

Optionally, the first insulating portion 40 can shield at least a portion of the P-type semiconductor layer 33 in the first direction Z.

Optionally, the arrangement manner of the second insulating portion 50 is similar to that of the first insulating portion 40, reference can be made to the relevant description of the first insulating portion 40, which will not be repeated herein.

Optionally, in an embodiment, as illustrated in FIG. 1, the second insulating portion 50 includes a first sub-portion 51 and a second sub-portion 52, and the first sub-portion 51 is connected with the second sub-portion 52. The first sub-portion 51 is disposed between the second conductive member 20 and the second side surface 312 of the light-emitting layer 31, the second sub-portion 52 exceeds a surface of the first sub-portion 51 facing the second conductive member 20, and the second sub-portion 52 is located between the second conductive member 20 and the N-type semiconductor layer 32.

By providing the light-emitting device 100 to further include the first insulating portion 40 and the second insulating portion 50, where the first insulating portion 40 isolates the light-emitting layer 31 from the first conductive member 10 and the second insulating portion 50 isolates the light-emitting layer 31 from the second conductive member 20, a short circuit caused by direct electrical connection between the first conductive member 10 and the second conductive member 20 can be avoided.

Optionally, as illustrated in FIG. 4, the light-emitting device 100 further includes a third conductive member 60 and a fourth conductive member 70, and the light-emitting layer 31 further has a third side surface 313 and a fourth side surface 314 opposite to each other, the third side surface 313 and the fourth side surface 314 each are connected with the first side surface 311 and the second side surface 312, the third conductive member 60 is opposite to at least a portion of the third side surface 313, the fourth conductive member 70 is opposite to at least a portion of the fourth side surface 314, and the third conductive member 60 is opposite to at least a portion of the fourth conductive member 70.

In an embodiment, as illustrated in FIG. 4, the first side surface 311 and the second side surface 312 are two opposite side surfaces of the light-emitting layer 31 in the third direction Y, and the third side surface 313 and the fourth side surface 314 are two opposite side surfaces of the light-emitting layer 31 in the second direction X. The first conductive member 10 is opposite to the first side surface 311, the second conductive member 20 is opposite to the second side surface 312, the third conductive member 60 is opposite to the third side surface 313, and the fourth conductive member 70 is opposite to the fourth side surface 314.

Optionally, the material of the third conductive member 60 is similar to that of the first conductive member 10, and the material of the fourth conductive member 70 is similar to that of the second conductive member 20, so reference can be made to the relevant description of the first conductive member 10 and the second conductive member 20, which will not be repeated herein.

Optionally, the third conductive member 60 is connected with the first conductive member 10, or the third conductive member 60 is spaced apart from the first conductive member 10, which is not limited herein.

Optionally, the third conductive member 60 is connected with the first conductive member 10, and/or the fourth conductive member 70 is connected with the second conductive member 20.

Optionally, as illustrated in FIG. 4, the light-emitting device 100 further includes a third insulating portion 80 and a fourth insulating portion 90, the third insulating portion 80 is disposed between the third side surface 313 and the third conductive member 60, and the fourth insulating portion 90 is disposed between the fourth side surface 314 and the fourth conductive member 70.

Optionally, after power is applied, a magnitude of a potential difference generated between the first conductive member 10 and the second conductive member 20 may be the same as or different from a magnitude of a potential difference generated between the third conductive member 60 and the fourth conductive member 70, which is not limited herein.

By providing such a light-emitting device 100, where the light-emitting device 100 further includes the third conductive member 60 and the fourth conductive member 70, the light-emitting layer 31 further has the third side surface 313 and the fourth side surface 314 opposite to each other, the third conductive member 60 is disposed opposite to at least a portion of the third side surface 313, and the fourth conductive member 70 is disposed opposite to at least a portion of the fourth side surface 314, the main migration directions of electrons and holes can be increased when power on, so that a probability of recombination between the electrons and the holes can be increased, thereby improving luminous efficacy of the light-emitting device 100.

In the description of the embodiments of the disclosure, it is to be noted that, the orientation or positional relationship indicated by the terms “center”, “upper”, “lower”, “left”, “right”, “vertical”, “horizontal”, “inside”, “outside”, and the like are based on the orientation or positional relationship depicted in the accompanying drawings. These terms are merely for the convenience of describing the disclosure and simplifying the description, rather than indicating or implying that the device or element referred to herein must have a specific orientation or be constructed and operated in a specific orientation, and therefore cannot be understood as a limitation on the disclosure.

While the above merely depicts some exemplary embodiments, the protection scope of the disclosure is not limited thereto. As will occur to those of ordinary skill in the art that all or part of the embodiments described above as well as the equivalent substitutes of the appended claims shall all fall in the scope of the disclosure.

What is claimed is:

1. A light-emitting device, comprising:
a light-emitting diode (LED) comprising an N-type semiconductor layer, a light-emitting layer, and a P-type semiconductor layer which are stacked sequentially in a first direction, the light-emitting layer having a first side surface and a second side surface opposite to each other in a second direction, the second direction intersecting with the first direction;
a first conductive member disposed opposite to at least a portion of the first side surface; and
a second conductive member disposed opposite to at least a portion of the second side surface, the first conductive member being disposed opposite to at least a portion of the second conductive member.

2. The light-emitting device of claim 1, wherein the LED further comprises a first current diffusion layer and a second current diffusion layer, the first current diffusion layer is stacked on the N-type semiconductor layer, the second current diffusion layer is stacked on the P-type semiconductor layer, and the first conductive member is disposed opposite to the second conductive member.

3. The light-emitting device of claim 2, wherein the first side surface faces the first current diffusion layer, and the first conductive member is connected with the first current diffusion layer.

4. The light-emitting device of claim 3, wherein the first conductive member is integrated with the first current diffusion layer.

5. The light-emitting device of claim 2, wherein the second conductive member is connected with the second current diffusion layer, and the second conductive member extends along the first direction and is opposite to a side surface of the P-type semiconductor layer.

6. The light-emitting device of claim 2, wherein the second conductive member is integrated with the second current diffusion layer.

7. The light-emitting device of claim 2, wherein the light-emitting device satisfies at least one of the following arrangements: the first conductive member is spaced apart from the first current diffusion layer, or the second conductive member is spaced apart from the second current diffusion layer.

8. The light-emitting device of claim 1, further comprising a first insulating portion and a second insulating portion, wherein the first insulating portion is disposed between the first side surface and the first conductive member, and the second insulating portion is disposed between the second side surface and the second conductive member.

9. The light-emitting device of claim 1, wherein the light-emitting device further comprises a third conductive member and a fourth conductive member, the light-emitting layer further has a third side surface and a fourth side surface opposite to each other in a third direction, the third direction intersects with the first direction and the second direction, the third conductive member is opposite to at least a portion of the third side surface, the fourth conductive member is opposite to at least a portion of the fourth side surface, and the third conductive member is opposite to at least a portion of the fourth conductive member.

10. The light-emitting device of claim 1, wherein the first conductive member and the second conductive member each are made of an electrode material, or the first conductive member and the second conductive member each are made of a semiconductor material.

11. A display apparatus, comprising a drive backplane and light-emitting devices arranged in an array on the drive backplane; each of the light-emitting devices comprising:
a light-emitting diode (LED) comprising an N-type semiconductor layer, a light-emitting layer, and a P-type semiconductor layer which are stacked sequentially in a first direction, the light-emitting layer having a first side surface and a second side surface opposite to each other in a second direction, the second direction intersecting with the first direction;
a first conductive member disposed opposite to at least a portion of the first side surface; and
a second conductive member disposed opposite to at least a portion of the second side surface, the first conductive member being disposed opposite to at least a portion of the second conductive member.

12. The display apparatus of claim 11, wherein the LED further comprises a first current diffusion layer and a second current diffusion layer, the first current diffusion layer is stacked on the N-type semiconductor layer, the second current diffusion layer is stacked on the P-type semiconductor layer, and the first conductive member is disposed opposite to the second conductive member.

13. The display apparatus of claim 12, wherein the first side surface faces the first current diffusion layer, and the first conductive member is connected with the first current diffusion layer.

14. The display apparatus of claim 13, wherein the first conductive member is integrated with the first current diffusion layer.

15. The display apparatus of claim 12, wherein the second conductive member is connected with the second current diffusion layer, and the second conductive member extends along the first direction and is opposite to a side surface of the P-type semiconductor layer.

16. The display apparatus of claim 12, wherein the second conductive member is integrated with the second current diffusion layer.

17. The display apparatus of claim 12, wherein the light-emitting device satisfies at least one of the following arrangements: the first conductive member is spaced apart from the first current diffusion layer, or the second conductive member is spaced apart from the second current diffusion layer.

18. The display apparatus of claim 11, wherein the light-emitting device further comprises a first insulating portion and a second insulating portion, wherein the first insulating portion is disposed between the first side surface and the first conductive member, and the second insulating portion is disposed between the second side surface and the second conductive member.

19. The display apparatus of claim 11, wherein the light-emitting device further comprises a third conductive member and a fourth conductive member, the light-emitting layer further has a third side surface and a fourth side surface opposite to each other in a third direction, the third direction intersects with the first direction and the second direction, the third conductive member is opposite to at least a portion of the third side surface, the fourth conductive member is opposite to at least a portion of the fourth side surface, and the third conductive member is opposite to at least a portion of the fourth conductive member.

20. The display apparatus of claim 11, wherein the first conductive member and the second conductive member each are made of an electrode material, or the first conductive member and the second conductive member each are made of a semiconductor material.
